(19) United States
(12) Patent Application Publication
(10) Pub. No.: US 2026/0305387 A1
(43) Pub. Date: Oct. 1, 2026

(54) PACKAGE WITH T-SHAPED SOURCE ELECTRODE

(71) Applicant: GaNrich Semiconductor Corporation, Hsinchu County (TW)

(72) Inventors: Sheng-Po Wang, Taoyuan City (TW); Chiao Fu, Hsinchu County (TW); Chen-Yu Wang, Taoyuan City (TW); Jia-Tay Kuo, Hsinchu County (TW)

(73) Assignee: GaNrich Semiconductor Corporation, Hsinchu County (TW)

(21) Appl. No.: 19/199,420

(22) Filed: May 6, 2025

(30) Foreign Application Priority Data
Mar. 25, 2025 (TW) 114111194

(51) Int. Cl. H01L 23/495; H01L 23/00

(52) U.S. Cl. CPC H10W 70/481; H10W 70/435; H10W 70/461; H10W 72/923; H10W 72/932; H10W 72/936; H10W 72/941; H10W 90/726

(57) ABSTRACT

A package includes a package bottom. The package bottom includes a lead frame and a molding compound. The lead frame includes a source electrode, a drain electrode, and a first gate electrode. The molding compound covers the lead frame and exposes the back side of the source electrode, the back side of the drain electrode, and the back side of the first gate electrode. The source electrode forms a first T-shape. The first T-shape includes a first beam and a first column. The first gate electrode is disposed at a first corner defined by the first beam and the first column, while the drain electrode is disposed at one side of the first beam.

### BACKGROUND OF THE INVENTION

### 1. Field of the Invention

The disclosure relates to an electrode layout of a package, particularly to an electrode layout with a T-shaped source electrode.

### 2. Description of the Prior Art

The package is the external structure of an electronic component, typically used to protect the component itself and provide electrical connections. The design of the package must not only consider heat dissipation but also take into account mechanical strength and protection from external environments. As electronic devices become increasingly miniaturized, packaging technology continues to evolve, from traditional pin packages to modern leadless packages. The choice of packaging method depends on various factors such as component's functions, size requirements, as well as heat dissipation and electrical performance.

Dual Flat No-lead (DFN) packaging and Quad Flat No-lead (QFN) packaging are both types of leadless packages. These two structures not only reduce the package size but also improve heat dissipation performance. Since the chip pads in DFN and QFN packages are exposed at the bottom of the package, they can be directly soldered to the circuit board. This allows for effective heat dissipation from the package. In addition to enhancing heat dissipation efficiency, this electrical connection also provides a more stable grounding effect, thereby improving the electrical performance of the component.

As the operating frequency and power consumption of chips continue to increase, heat dissipation has become an increasingly prominent issue in high-performance chips. Effectively extracting heat from the chip has become a challenge. If the chip temperature becomes too high, it may lead to performance degradation, component damage, or a shortened lifespan. Therefore, improving the heat dissipation performance of the package has become a key area of focus in current efforts.

### SUMMARY OF THE INVENTION

According to an embodiment of the present disclosure, a package includes a package bottom. The package bottom includes a lead frame including a source electrode, a drain electrode, and a first gate electrode. A molding compound covers the lead frame and exposes a back side of the source electrode, a back side of the drain electrode, and a back side of the first gate electrode. The source electrode forms a first T-shape. The first T-shape includes a first beam and a first column, the first gate electrode is disposed at a first corner defined by the first beam and the first column, and the drain electrode is disposed at one side of the first beam.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a back side of a bottom of a package according to a first embodiment disclosed in the present disclosure.

FIG. 2 shows a back side of a package bottom according to a second embodiment of the present disclosure.

FIG. 3 shows a back side of a package bottom according to a third embodiment of the present disclosure.

FIG. 4 shows a back side of a package bottom according to a fourth embodiment of the present disclosure.

FIG. 5 shows a back side of a package bottom according to a fifth embodiment of the present disclosure.

FIG. 6 shows a back side of a package bottom according to a sixth embodiment of the present disclosure.

FIG. 7 shows a back side of a package bottom according to a seventh embodiment of the present disclosure.

FIG. 8 shows chips according to several embodiments of the present disclosure.

FIG. 9 is a varied type of the chip shown in FIG. 8 of the present disclosure.

FIG. 10 shows a chip depicted in FIG. 8 of the present disclosure along with solder balls on the chip.

FIG. 11 shows the chip depicted in FIG. 9 of the present disclosure along with solder balls on the chip.

FIG. 12 shows a sectional view of a package according to one embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

Although this disclosure uses terms such as first, second, third, etc., to describe various components, parts, regions, layers, and/or sections, it should be understood that these components, parts, regions, layers, and/or sections should not be limited by these terms. These terms are merely used to distinguish one component, part, region, layer, and/or section from another, and do not inherently represent any precedence in sequence, nor do they represent the arrangement order or manufacturing sequence between one element and another. Therefore, within the scope of the specific embodiments of this disclosure, the first component, part, region, layer, or section discussed below can also be referred to by the terms of the second component, part, region, layer, or section.

Although the disclosure is described with respect to specific embodiments, the principles of the disclosure, as defined by the claims appended herein, may obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

In the present disclosure, the back side of the package bottom will be used for direct attachment to the surface of a circuit board, while the front of the package bottom will be used for bonding with a chip. The front and back side of the package bottom are opposite to each other.

FIG. 1 shows a back side of a bottom of a package according to a first embodiment disclosed in this disclosure. As shown in FIG. 1, a package 10 disclosed in this disclosure includes a package bottom 10a. The package bottom 10a includes a lead frame 12. The lead frame 12 includes a source electrode SE, a drain electrode DE, a first gate electrode GE1, and numerous pins P surrounding the source electrode SE, the drain electrode DE, and the first gate electrode GE1. A molding compound 14 covers the lead frame 12 and exposes the back side of the source electrode SE, the back side of the drain electrode DE, and the back side of the first gate electrode GE1 through the molding compound 14. The package bottom 10a is in a shape of a first rectangle 16. The first rectangle 16 includes a first region (marked by dashed lines) 16a and a second region (marked by dashed lines) 16b. The first region 16a and the second region 16b are rectangular, and the first region 16a and the second region 16b are arranged side by side along a Y-axis. The source electrode SE and the first gate electrode GE1 are disposed in the second region 16b, while the drain electrode DE is disposed in the first region 16a. Moreover, as seen from the top view, the source electrode SE of the present disclosure forms a first T-shape 18 by using only one source electrode SE. The first T-shape 18 includes a first beam 18a and a first column 18b. The first gate electrode GE1 is disposed at a first corner C1 defined by the first beam 18a and the first column 18b. The drain electrode DE is disposed on one side of the first beam 18a. In the first embodiment, the first column 18b of the first T-shape 18 points to the direction away from the drain electrode DE. Additionally, the drain electrode DE and the first gate electrode GE1 are disposed on opposite sides of the first beam 18a. Furthermore, by placing the first gate electrode GE1 at the first corner C1 simplifies the wiring layout on the circuit board.

The distance between the drain electrode DE and the source electrode SE is determined based on the insulation distance required by the circuit board's voltage withstand safety production compliance. Therefore, the distance can be adjusted according to different requirements. For example, when the distance is 1.5 millimeters, the drain electrode DE and the source electrode SE can withstand a voltage of 300V; when the distance is 1 millimeter, the drain electrode DE and the source electrode SE can withstand a voltage of 200V.

Furthermore, the back side of the package bottom 10a only has one source electrode SE and one drain electrode DE. The source electrode SE and the drain electrode DE are arranged in a large-area configuration, occupying most of the area of the package bottom 10a. For example, the package bottom 10a is in a shape of a first rectangle 16, and the summation of the area of the source electrode SE, the area of the drain electrode DE, and the area of the first gate electrode GE1 is 70% to 95% of the area of the first rectangle 16. As a result, as the summation of areas of all the electrodes increases, the heat dissipation area is enlarged, and the thermal efficiency of the package 10 is improved. Additionally, according to one embodiment of the present disclosure, the area of the drain electrode DE is larger than the area of the source electrode SE. For example, the area of the source electrode SE is 0.6 to 0.95 times of the area of the drain electrode DE. In this way, the drain electrode DE which withstands higher voltage can achieve better heat dissipation performance.

Furthermore, the structure of the lead frame 12 on the back side of the package bottom 10a is the same as the structure of the lead frame 12 on the front side of the package bottom 10a. In other words, shapes and relative positions of the source electrode SE, the drain electrode DE, and the first gate electrode GE1 on the front side of the package bottom 10a are the same as shapes and relative positions of the source electrode SE, the drain electrode DE, and the first gate electrode GE1 on the back side of the package bottom 10a.

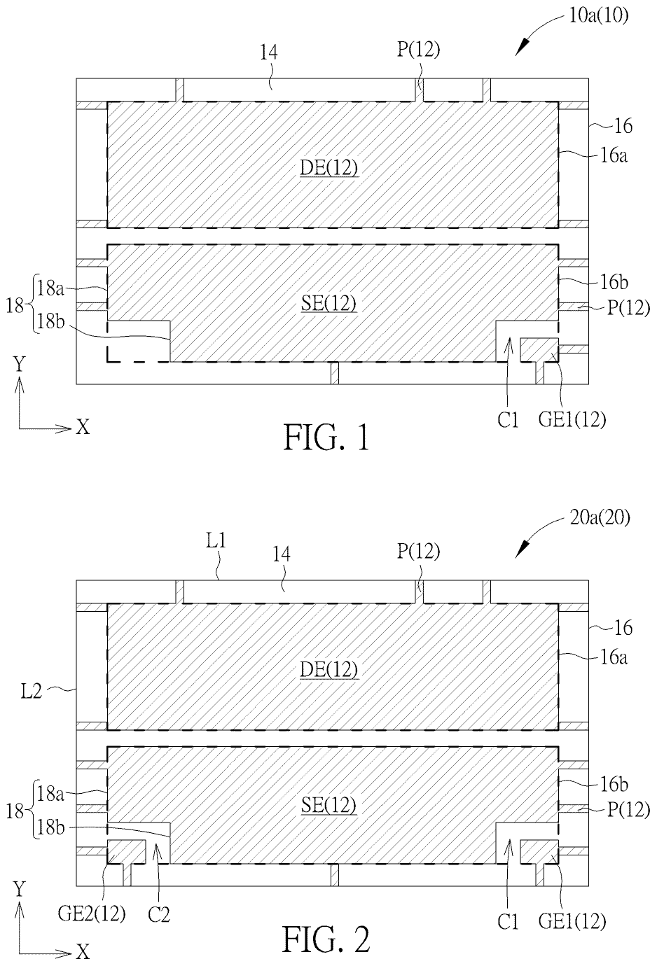

FIG. 2 shows a back side of a package bottom according to a second embodiment of the present disclosure, wherein elements with the same functions and positions will be designated with the same reference numerals as those in the first embodiment. As shown in FIG. 2, the difference between the package bottom 20a of the package 20 in the second embodiment and the package bottom 10a of the package 10 in the first embodiment is that a second gate electrode GE2 is disposed at a second corner C2 defined by the first beam 18a and the first column 18b. In other words, the first gate electrode GE1 and the second gate electrode GE2 are located on opposite sides of the first column 18b. This position configuration helps shorten the wiring distance from a control chip to the first gate electrode GE1 and to the second gate electrode GE2, thereby simplifying the routing path. Furthermore, a summation of an area of the source electrode SE, an area of the drain electrode DE, an area of the first gate electrode GE1, and an area of the second gate electrode GE2 is 70% to 95% of the area of the first rectangle 16. The positions and materials of the other elements on the package bottom 20a are the same as those in the first embodiment and the description will be omitted here. In subsequent embodiments, two gate electrodes, such as the first gate electrode GE1 and the second gate electrode GE2, will be used as examples. However, in practical applications, it is possible to use only one gate electrode.

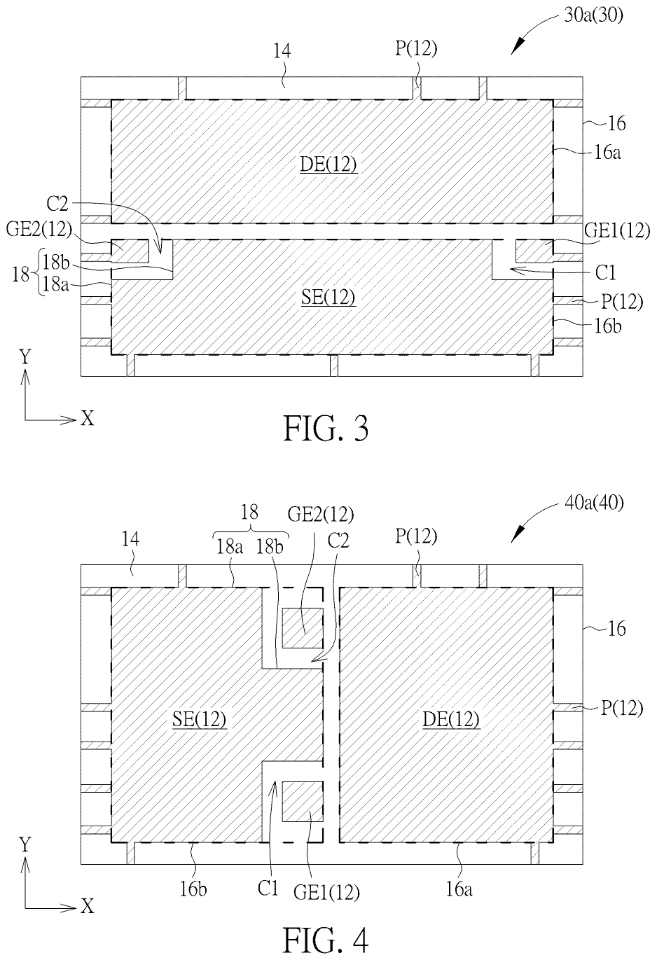

FIG. 3 shows a back side of a package bottom according to a third embodiment of the present disclosure, wherein elements with the same functions and positions will be designated with the same reference numerals as those in the second embodiment. As shown in FIG. 3, the difference between the package bottom 30a of the package 30 in the third embodiment and the package bottom 20a of the package 20 in the second embodiment is that the first column 18b of the first T-shape 18 on the package bottom 30a points to the drain electrode DE. As a result, the first gate electrode GE1 and the second gate electrode GE2 are sandwiched between the drain electrode DE and the source electrode SE. The positions and materials of the other elements on the package bottom 30a are the same as those in the second embodiment and the description will be omitted here.

FIG. 4 shows a back side of a package bottom according to a fourth embodiment of the present disclosure, wherein elements with the same functions and positions will be designated with the same reference numerals as those in the third embodiment. As shown in FIG. 4, the difference between the package bottom 40a of the package 40 in the fourth embodiment and the package bottom 30a of the package 30 in the third embodiment is that the first region 16a and the second region 16b of the first rectangle 16 on the package bottom 40a are arranged side by side along an X-axis. The positions and materials of the other elements on the package bottom 40a are the same as those in the third embodiment and the description will be omitted here.

FIG. 5 shows a back side of a package bottom according to a fifth embodiment of the present disclosure, wherein elements with the same functions and positions will be designated with the same reference numerals as those in the second embodiment. As shown in FIG. 5, the difference between the package bottom 50a of the package 50 in the fifth embodiment and the package bottom 20a of the package 20 in the second embodiment is that the first region 16a and the second region 16b of the first rectangle 16 on the package bottom 50a are arranged side by side along an X-axis. The positions and materials of the other elements on the package bottom 50a are the same as those in the second embodiment and the description will be omitted here.

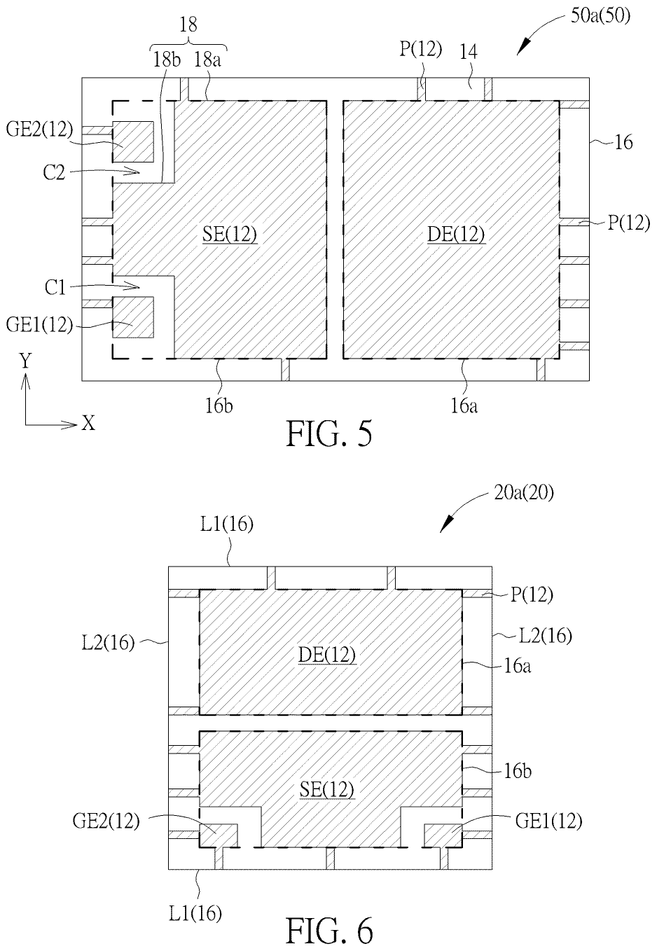

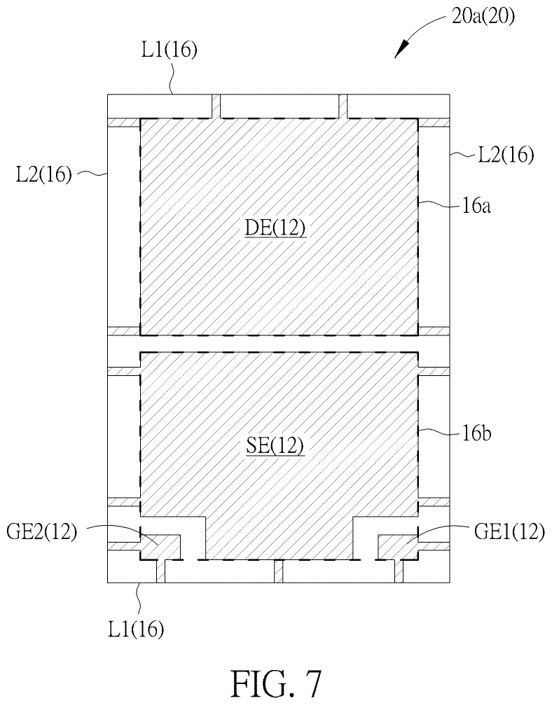

In the case where the relative positions of the drain electrode DE, the source electrode SE, the first gate electrode GE1 in the first embodiment and the relative positions of the drain electrode DE, the source electrode SE, the first gate electrode GE1 and the second gate electrode GE2 in the second embodiment through the fifth embodiments are the same, the edges of the respective packages in the first embodiment through fifth embodiments can be adjusted according to different requirements. The following description will demonstrate the variation in edges by using FIG. 2, FIG. 6, and FIG. 7. FIG. 6 shows a back side of the package bottom according to a sixth embodiment of the present disclosure. FIG. 7 shows a back side of a package bottom according to a seventh embodiment of the present disclosure. Elements with the same functions and positions in FIG. 6 and FIG. 7 will be designated with the same reference numerals as those in the second embodiment.

The layouts of the drain electrode DE, the source electrode SE, the first gate electrode GE1, and the second gate electrode GE2 in FIG. 2, FIG. 6, and FIG. 7 are the same. The first rectangle 16 of the package bottom 20a includes a first edge L1 and a second edge L2. The first edge L1 is parallel to the X-axis, and the second edge L2 is parallel to the Y-axis. In FIG. 2, the first edge L1 of the first rectangle 16 of the package bottom 20a is greater than the second edge L2. In FIG. 6, the first edge L1 of the first rectangle 16 of the package bottom 20a is equal to the second edge L2. In FIG. 7, the first edge L1 of the first rectangle 16 of the package bottom 20a is smaller than the second edge L2.

The packages disclosed herein can be applied to both dual flat no-lead (DFN) packages and quad flat no-lead (QFN) packages. The packages of the present disclosure are particularly suitable for packaging high electron mobility transistor (HEMT) chips. The HEMT can be a gallium nitride (GaN) HEMT or other suitable III-V compound semiconductor HEMTs. According to one embodiment, the packages can be used to encapsulate a single chip, such as an HEMT, or further include resistors and capacitors, but is not limited to this.

The HEMT chip of the present disclosure will be stacked on the front side of the package bottom and directly bonded to the source electrode, the drain electrode, the first gate electrode, and the second gate electrode on the front side of the package bottom by using solder balls. For direct bonding, the positions and the shapes of the source pad, the drain pad, the first gate pad, and the second gate pad on the chip must correspond to the positions and the shapes of the source electrode, the drain electrode, the first gate electrode, and the second gate electrode on the package bottom. In other words, the layouts of the source pad, the drain pad, the first gate pad, and the second gate pad must be the same as the layout of the source electrode, the drain electrode, the first gate electrode, and the second gate electrode.

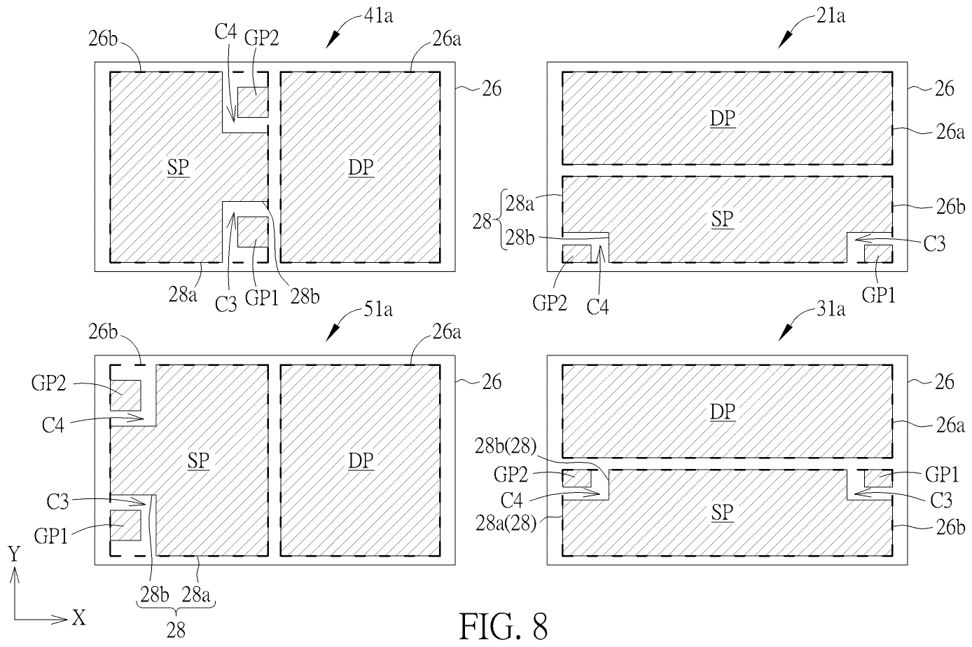

FIG. 8 shows chips according to several embodiments of the present disclosure. The chip 21a in FIG. 8 corresponds to the package bottom 20a in the second embodiment. The chip 21a includes a source pad SP, a drain pad DP, a first gate pad GP1, and a second gate pad GP2 disposed on the top surface of the chip 21a. The source pad SP forms a second T-shape 28 using only one source pad SP. The second T-shape 28 includes a second beam 28a and a second column 28b. The first gate pad GP1 is positioned at a third corner C3 defined by the second beam 28a and the second column 28b. The second gate pad GP2 is positioned at a fourth corner C4 defined by the second beam 28a and the second column 28b. The drain pad DP is positioned on one side of the second beam 28a. The drain pad DP forms a rectangle by using only one drain pad DP. The area of the source pad SP is 0.7 to 0.95 times of the area of the drain pad DP. A summation of an area of the source pad SP, an area of the drain pad DP, an area of the first gate pad GP1 and an area of the second gate pad GP2 is between 70% and 95% of an area of the top surface of the chip 21a.

The top surface of the chip 21a is a second rectangle 26. The second rectangle 26 includes a third region 26a (marked by dashed lines) and a fourth region 26b (marked by dashed lines). The third region 26a and the fourth region 26b are arranged side by side along the Y-axis. The source pad SP, the first gate pad GP1, and the second gate pad GP2 are positioned in the fourth region 26b. The drain pad DP is positioned in the third region 26a. The second column 28b of the second T-shape 28 points to the direction away from the drain pad DP.

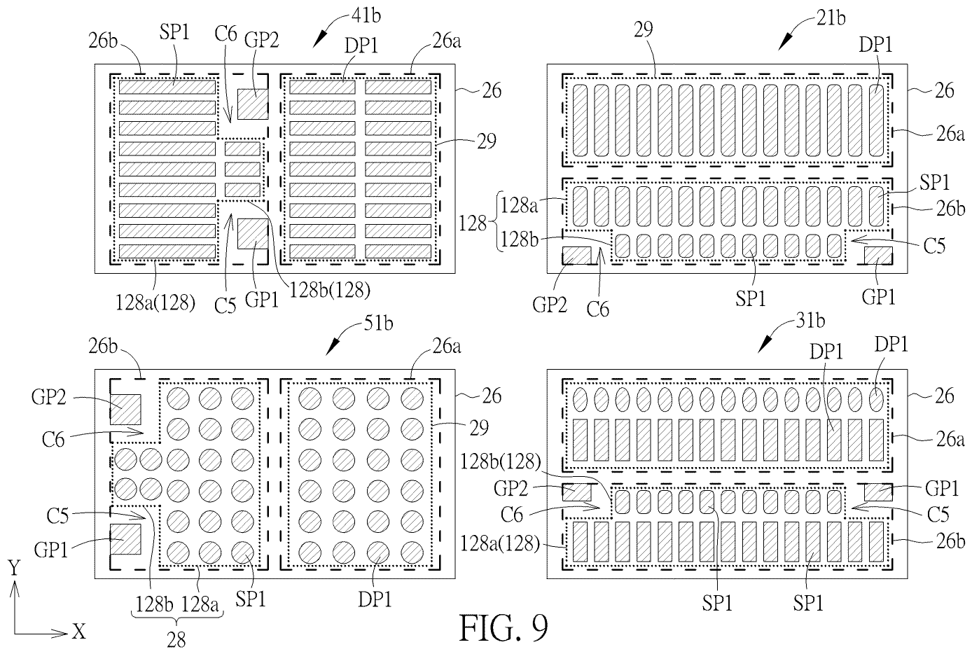

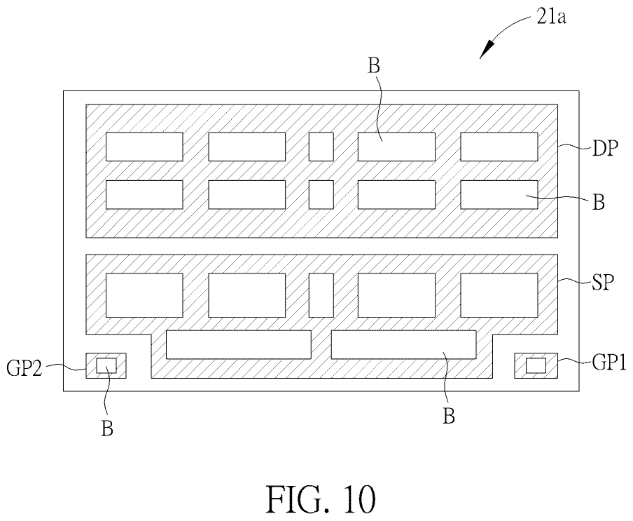

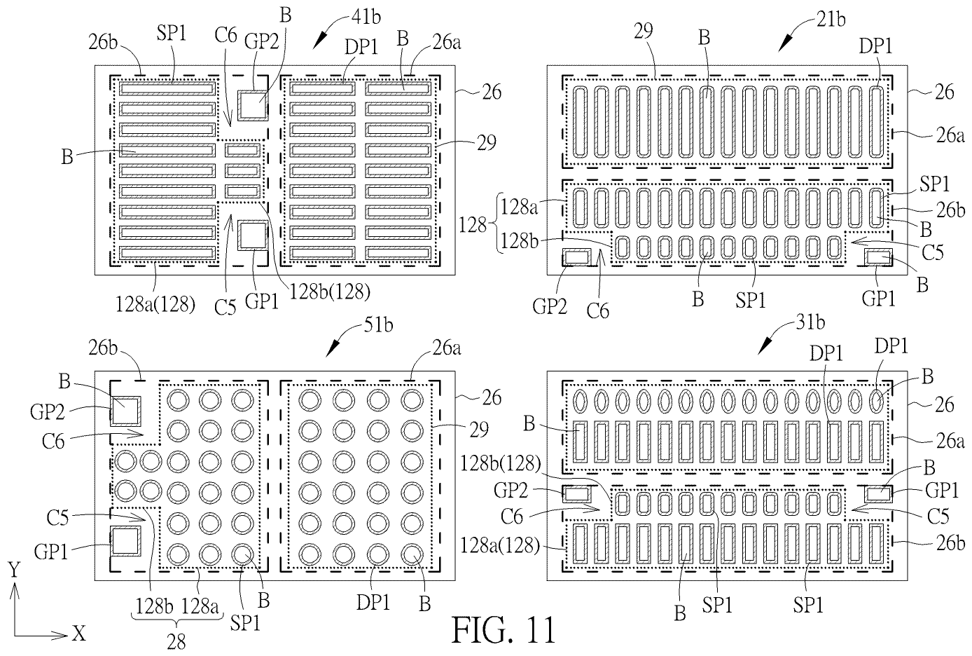

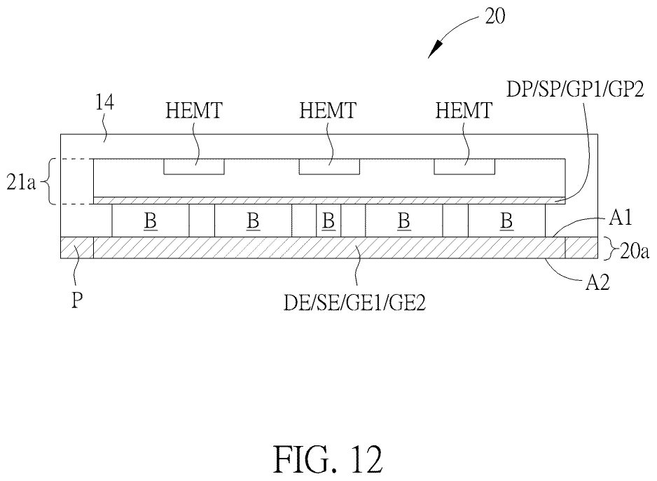

In summary, the relative positions and shapes of the source pad SP, the drain pad DP, the first gate pad GP1, and the second gate pad GP2 on the chip 21a are the same as the source electrode SE, the drain electrode DE, the first gate electrode GE1, and the second gate electrode GE2 on the package bottom 20a. The source pad SP, the drain pad DP, the first gate pad GP1, and the second gate pad GP2 on the chip 21a can each be proportionally scaled down relative to the source electrode SE, the drain electrode DE, the first gate electrode GE1, and the second gate electrode GE2, or the source pad SP, the drain pad DP, the first gate pad GP1, and the second gate pad GP2 on the chip 21a can each be of equal size respectively to the source electrode SE, the drain electrode DE, the first gate electrode GE1, and the second gate electrode GE2. FIG. 10 shows a chip depicted in FIG. 8 of the present disclosure along with solder balls on the chip. FIG. 11 shows the chip depicted in FIG. 9 of the present disclosure along with solder balls on the chip. FIG. 12 shows a sectional view of a package according to one embodiment of this disclosure, where elements with the same function and position are designated by using the same reference numbers as those in FIG. 2 and FIG. 8.

As shown in FIG. 12, the package 20 is formed by combining the package bottom 20a from the second embodiment in FIG. 2 with the chip 21a from FIG. 8. As shown in FIG. 10, according to one embodiment, the package 20 includes a single chip 21a, and the chip 21a includes at least one high electron mobility transistor HEMT.

As shown in FIG. 10, multiple solder balls B are placed on the source pad SP, the drain pad DP, the first gate pad GP1, and the second gate pad GP2 on the chip 21a. The solder balls B directly contact the source pad SP, the drain pad DP, the first gate pad GP1, and the second gate pad GP2. Please refer to FIG. 2, FIG. 9, and FIG. 10. In FIG. 9, the solder balls B on the chip 21a face toward the front side A1 of the package bottom 20a shown in FIG. 2. The front side A1 and the back side A2 of the package bottom 20a are opposite to each other. The top view of the back side A2 of the package bottom 20a in FIG. 10 is the package bottom 20a shown in FIG. 2. The source pad SP is joined/contacted with the front side of the source electrode SE through the solder balls B. The drain pad DP is joined/contacted with the front side of the drain electrode DE through the solder balls B. The first gate pad GP1 is joined/contacted with the front side of the first gate electrode GE1 through the solder balls B. The second gate pad GP2 is joined/contacted with the front side of the second gate electrode GE2 through the solder balls B. The source pad SP completely overlaps the source electrode SE. The drain pad DP completely overlaps the drain electrode DE. The first gate pad GP1 completely overlaps the first gate electrode GE1. The second gate pad GP2 completely overlaps the second gate electrode GE2. The molding compound 14 fills the gaps between the chip 21a, the lead frame 12, and the solder balls B.

Please refer again to FIG. 8. The source pad SP, the drain pad DP, the first gate pad GP1, and the second gate pad GP2 of chips 21a/31a/41a/51a can each have their own layout. However, the layouts of the source pad SP, the drain pad DP, the first gate pad GP1, and the second gate pad GP2 must correspond to the layout of the package bottom, which has the same layout for the source electrode SE, the drain electrode DE, the first gate electrode GE1, and the second gate electrode GE2. For example, the chip 31a needs to use the package bottom 30a from the third embodiment, the chip 41a needs to use the package bottom 40a from the fourth embodiment, and the chip 51a needs to use the package bottom 50a from the fifth embodiment. The relative positions and shapes of the source pad SP, the drain pad DP, the first gate pad GP1, and the second gate pad GP2 in chips 31a/41a/51a correspond to the source electrode SE, the drain electrode DE, the first gate electrode GE1, and the second gate electrode GE2 of the package bottoms 30a/40a/50a, respectively. The detail descriptions will not be repeated here.

In addition, FIG. 9 is a varied type of the chip shown in FIG. 8 of the present disclosure, where elements with the same function and position will use the same reference numbers as those in FIG. 8.

The layouts of the chips 21b/31b/41b/51b in FIG. 9 are the same as those of the chips 21a/31a/41a/51a, except that the shapes and quantities of the source pads SP and the drain pads DP in chips 21b/31b/41b/51b differ from those in chips 21a/31a/41a/51a. Similarly, chips 21b/31b/41b/51b are respectively required to use package bottoms 20a/30a/40a/50a.

In detail, chips 21b/31b/41b/51b each have multiple source pads SP1 and multiple drain pads DP1. All the source pads SP1 are arranged in a T-shaped profile 128 (marked by dotted lines). The T-shaped profile 128 includes a third beam 128a and a third column 128b. The third beam 128a and the third column 128b define a fifth corner C5 and a sixth corner C6, with the first gate pad GP1 and the second gate pad GP2 being respectively disposed at the fifth corner C5 and the sixth corner C6. In addition, the distribution of all drain pads DP1 is arranged in a rectangular profile 29 (marked by dotted lines). The shape of each source pad SP1 includes a rectangle, a rounded rectangle, a circle, or an ellipse, and the shape of each drain pad DP1 includes a rectangle, a rounded rectangle, a circle, or an ellipse. For example, the source pads SP1 and the drain pads DP1 in the chip 41b are in shapes of rectangles, while the source pads SP1 and the drain pads DP1 in chip 21b are in shapes of rounded rectangles. The source pads SP1 and the drain pads DP1 in the chip 51b are in shapes of circles. Shapes of the source pads SP1 in chip 31b include rectangles and rounded rectangles, while shapes of the drain pads DP1 include ellipses and rectangles. Shapes of the drain pad DP1 include ellipses and rectangles. Depending on the internal wiring design of different chips, the source pads SP1 and the drain pads DP1 can have different shapes and quantities, not limited to the shapes mentioned above.

FIG. 11 depicts the chip and the solder balls on the chip shown in FIG. 9 of the present disclosure. As shown in FIG. 11, in the case of chips with the same layout, the source pad SP1 and the drain pad DP1 of chips 21b/31b/41b/51b in FIG. 9 can have changes in shape and quantity. Under this condition, solder balls B will be placed on each source pad SP1 and each drain pad DP1, and the shape of solder balls B will be the same as the shape of the source pad SP1 or the drain pad DP1 on which the solder ball B is located. In other words, the shape of the solder ball B includes a rectangle, a rounded rectangle, a circle, or an ellipse. For example, in the chip 31b, the shapes of the source pad SP1 include rectangle and rounded rectangle, while the shapes of the drain pads DP1 include circles and ellipses. Therefore, the solder ball B on the rectangular source pad SP1 will be rectangular, and the solder ball B on the rounded rectangular source pad SP1 will be rounded rectangular. The solder balls B on the circular drain pad DP1 will have a circular shape, and the solder balls B on the elliptical drain pad DP1 will have an elliptical shape. The method of assembling the chips 21b/31b/41b/51b into the package is the same as those for chips 21a/31a/41a/51a, and will not be repeated here.

Since the layout of the source pad, the drain pad, the first gate pad, and the second gate pad on the chip is the same as that of the source electrode, the drain electrode, the first gate electrode, and the second gate electrode on the package bottom, there is no need for redistribution layers. The source pad, the drain pad, the first gate pad, and the second gate pad can be directly joined and electrically connected to the source electrode, the drain electrode, the first gate electrode, and the second gate electrode through solder balls. In this way, wiring complexity is reduced, circuit design is simplified, and heat dissipation efficiency is improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package, comprising:
a package bottom, wherein the package bottom comprises:
a lead frame comprising a source electrode, a drain electrode, and a first gate electrode;
a molding compound covering the lead frame and exposing a back side of the source electrode, a back side of the drain electrode, and a back side of the first gate electrode; wherein the source electrode forms a first T-shape, the first T-shape comprises a first beam and a first column, the first gate electrode is disposed at a first corner defined by the first beam and the first column, and the drain electrode is disposed at one side of the first beam.

2. The package of claim 1, wherein the package bottom is in a shape of a first rectangle, the first rectangle comprises a first region and a second region, the first region and the second region are arranged side by side along a Y-axis, the source electrode and the first gate electrode are disposed in the second region, the drain electrode is disposed in the first region, and the first column of the first T-shape points to a direction away from the drain electrode.

3. The package of claim 1, wherein the package bottom is in a shape of a first rectangle, the first rectangle comprises a first region and a second region, the first region and the second region are arranged side by side along a Y-axis, the source electrode and the first gate electrode are disposed in the second region, the drain electrode is disposed in the first region, and the first column of the first T-shape points to the drain electrode.

4. The package of claim 1, wherein the package bottom is in a shape of a first rectangle, the first rectangle comprises a first region and a second region, the first region and the second region are arranged side by side along an X-axis, the source electrode and the first gate electrode are disposed in the second region, the drain electrode is disposed in the first region, and the first column of the first T-shape points to a direction away from the drain electrode.

5. The package of claim 1, wherein the package bottom is in a shape of a first rectangle, the first rectangle comprises a first region and a second region, the first region and the second region are arranged side by side along an X-axis, the source electrode and the first gate electrode are disposed in the second region, the drain electrode is disposed in the first region, and the first column of the first T-shape points to the drain electrode.

6. The package of claim 1, wherein a back side of the package bottom has only a source electrode and a drain electrode.

7. The package of claim 1, wherein an area of the drain electrode is greater than an area of the source electrode.

8. The package of claim 7, wherein the area of the source electrode is 0.6 to 0.95 times of the area of the drain electrode.

9. The package of claim 1, wherein the package bottom is in a shape of a first rectangle, and a summation of an area of the source electrode, an area of the drain electrode, and an area of the first gate electrode is between 70% and 95% of an area of the first rectangle.

10. The package of claim 1, wherein the package bottom is in a shape of a first rectangle, the first rectangle comprises a first edge and a second edge, the first edge is parallel to an X-axis, and the second edge is parallel to a Y-axis, wherein relationships between the first edge and the second edge comprises: the first edge being equal to the second edge, the first edge being greater than the second edge, or the first edge being smaller than the second edge.

11. The package of claim 1, further comprising a second gate electrode disposed at a second corner defined by the first beam and the first column.

12. The package of claim 1, further comprising:
a chip comprising a source pad, a drain pad, and a first gate pad disposed on a top surface of the chip, wherein a shape of the source pad is the same as a shape of the source electrode, a shape of the drain pad is the same as a shape of the drain electrode, and a shape of the first gate pad is the same as a shape of the first gate electrode;
a plurality of solder balls respectively contacting the source pad, the drain pad, and the first gate pad;
wherein the source pad is joined to a front side of the source electrode by the solder balls, the drain pad is joined to a front side of the drain electrode by the solder balls, the first gate pad is joined to a front side of the first gate electrode by the solder balls, the source pad completely overlaps the source electrode, the drain pad completely overlaps the drain electrode, the first gate pad completely overlaps the first gate electrode, and the molding compound fills gaps respectively between the chip, the lead frame, and the solder balls.

13. The package of claim 1, further comprising:
a chip comprising a source pad, a drain pad, and a first gate pad disposed on a top surface of the chip, wherein:
the source pad forms a second T-shape, the second T-shape comprises a second beam and a second column, the first gate pad is disposed at a third corner defined by the second beam and the second column, and the drain pad is disposed on one side of the second beam.

14. The package of claim 13, wherein an area of the source pad is 0.7 to 0.95 times of an area of the drain pad.

15. The package of claim 13, wherein a summation of an area of the source pad, an area of the drain pad, and an area of the first gate pad is between 70% and 95% of an area of the top surface of the chip.

16. The package of claim 12, wherein the chip is a high electron mobility transistor chip.

17. The package of claim 1, further comprising:
a chip comprising a plurality of source pads, a plurality of drain pads, and a first gate pad disposed on a top surface of the chip, wherein:
the source pads are arranged in a T-shaped profile, the T-shaped profile comprises a third beam and a third column, the first gate pad is disposed at a fifth corner defined by the third beam and the third column, the drain pads is disposed on one side of the third beam, and the drain pads are arranged in a rectangular profile.

18. The package of claim 17, wherein a shape of each of the source pads comprises a rectangle, a rounded rectangle, a circle, or an ellipse, and a shape of each of the drain pads comprises a rectangle, a rounded rectangle, a circle, or an ellipse.

19. The package of claim 17, wherein a total area of the source pads is 0.7 to 0.95 times of a total area of the drain pads.

20. The package of claim 17, wherein a summation of a total area of the source pads, a total area of the drain pads, and an area of the first gate pad is between 70% and 95% of an area of the top surface of the chip.
